(19) United States
(12) Patent Application Publication
(10) Pub. No.: US 2026/0149441 A1
(43) Pub. Date: May 28, 2026

(54) DUTY CYCLE MONITORING CIRCUIT AND SEMICONDUCTOR APPARATUS USING THE SAME

(71) Applicant: SK hynix Inc., Icheon-si Gyeonggi-do (KR)

(72) Inventors: Hyun Kyu PARK, Icheon-si Gyeonggi-do (KR); Yang Ho SUR, Icheon-si Gyeonggi-do (KR); Dong Wook JANG, Icheon-si Gyeonggi-do (KR)

(73) Assignee: SK hynix Inc., Icheon-si Gyeonggi-do (KR)

(21) Appl. No.: 19/076,520

(22) Filed: Mar. 11, 2025

(30) Foreign Application Priority Data
Nov. 25, 2024 (KR) 10-2024-0169687

(51) Int. Cl. H03K 5/156; H03K 3/017

(52) U.S. Cl. CPC H03K 5/1565; H03K 3/017

(57) ABSTRACT

A duty cycle monitoring circuit includes a duty cycle reduction circuit, a duty cycle detection circuit, and a latch circuit. The duty cycle reduction circuit reduces duty cycles of a first clock signal and a second clock signal to generate a first input signal and a second input signal. The duty cycle detection circuit detects duty cycles of the first input signal and a second input signal to generate a first output signal and a second output signal. The latch circuit generates a duty detection signal based on the first output signal and the second output signal.

### CROSS-REFERENCES TO RELATED APPLICATION

The present application claims priority under 35 U.S.C. § 119(a) to Korean Patent Application No. 10-2024-0169687, filed in the Korean Intellectual Property Office on Nov. 25, 2024, the entire contents of which application is incorporated herein by reference.

### BACKGROUND

### 1. Technical Field

The present application relates to integrated circuit technology, including but not limited to a duty cycle monitoring circuit and a semiconductor apparatus using the duty cycle monitoring circuit.

### 2. Related Art

An electronic device includes numerous electronic components, among which a computer system includes many semiconductor apparatus including semiconductor devices. Semiconductor apparatus included in the computer system communicate with each other by transmitting and receiving system clock signals and data signals. The semiconductor apparatus operate in synchronization with clock signals. As operating speed of the computer system and frequency of the system clock signals increase, a pulse width of the system clock signals decreases and setup and hold margins needed to synchronize the data signals with the system clock signals decrease.

A semiconductor apparatus may sample data signals in synchronization with the system clock signals or internal clock signals generated by delaying or dividing the system clock signals. A duty cycle of the system clock signals or the internal clock signals remains consistent to result in accurately sampled data signals. When the duty cycle fluctuates, the setup and hold margins that sample the data signals may change, potentially causing malfunctions and leading to reliability issues in the semiconductor apparatus.

### SUMMARY

In an embodiment, a duty cycle monitoring circuit may include a duty cycle reduction circuit, a duty cycle detection circuit, and a latch circuit. The duty cycle reduction circuit may be configured to receive a first clock signal and a second clock signal, to reduce a duty cycle of the first clock signal by an amount to generate a first input signal, and to reduce a duty cycle of the second clock signal by the amount to generate a second input signal. The duty cycle detection circuit may be configured to detect the duty cycle of the first input signal and the second input signal to generate a first output signal and a second output signal. The latch circuit may be configured to generate a duty detection signal when one of the first output signal and the second output signal reaches a trigger voltage.

In an embodiment, a duty cycle monitoring circuit may include a clock chopper circuit, a duty cycle reduction circuit, a duty cycle monitoring circuit, and a latch circuit. The clock chopper circuit may be configured to receive a first clock signal and a second clock signal and output, based on a flip signal, a first of the first clock signal and the second clock signal as a first select clock signal and a second of the first clock signal and the second clock signal as a second select clock signal. The duty cycle reduction circuit may be configured to reduce duty cycles of the first select clock signal and the second select clock signal by an amount to generate a first input signal and a second input signal. The duty cycle detection circuit may be configured to detect duty cycles of the first input signal and the second input signal to generate a first output signal and a second output signal. The latch circuit may be configured to generate a duty detection signal based on the first output signal and the second output signal.

In an embodiment, a semiconductor apparatus may include a strobe reception circuit, a first duty adjustment circuit, a data reception circuit, and a duty cycle monitoring circuit. The strobe reception circuit may be configured to receive a first strobe signal and a second strobe signal from an external device. The first duty adjustment circuit may be configured to adjust duty cycles of the first strobe signal and the second strobe signal based on a first duty control signal to generate a first internal strobe signal and a second internal strobe signal, respectively. The data reception circuit may be configured to receive data in synchronization with the first internal strobe signal and the second internal strobe signal. The duty cycle monitoring circuit may be configured to reduce the duty cycles of the first internal strobe signal and the second internal strobe signal by an amount to generate a first input signal and a second input signal and to detect the duty cycles of the first input signal and the second input signal to generate a duty detection signal. The first duty control signal may be generated based on the duty detection signal.

In an embodiment, a method may include reducing a duty cycle of a first clock signal by an amount to generate a first input signal and reducing a duty cycle of a second clock signal by the amount to generate a second input signal; generating a first output signal based on a duty cycle of the first input signal and generating a second output signal based on a duty cycle of the second input signal; and generating a duty detection signal when one of the first output signal and the second output signal reaches a trigger voltage.

### BRIEF DESCRIPTION OF THE DRAWINGS

FIG. 1 is a diagram illustrating a configuration of a duty cycle monitoring circuit according to an embodiment.

FIG. 2 is a timing diagram during operation of a duty cycle monitoring circuit according to an embodiment.

FIG. 3 is a diagram illustrating a configuration of a duty cycle monitoring circuit according to an embodiment.

FIG. 4A is a diagram illustrating a configuration of a reduction circuit according to an embodiment.

FIG. 4B is a diagram illustrating a buffer of a reduction circuit according to an embodiment.

FIG. 4C is a timing diagram during operation of a duty cycle reduction circuit according to an embodiment.

FIG. 5 is a timing diagram during operation of a duty cycle monitoring circuit according to an embodiment.

FIG. 6A is a diagram illustrating a configuration of a reduction circuit according to an embodiment.

FIG. 6B is a timing diagram during operation of a duty cycle reduction circuit illustrated according to an embodiment.

FIG. 7 is a timing diagram during operation of a duty cycle monitoring circuit according to an embodiment.

FIG. 8 is a diagram illustrating a configuration of a duty cycle monitoring circuit according to an embodiment.

FIG. 9 is a diagram illustrating a configuration of a semiconductor apparatus in accordance with an embodiment.

FIG. 10 is a timing diagram during operation of the semiconductor apparatus according to an embodiment.

FIG. 11 is a diagram illustrating a configuration of a semiconductor system in accordance with an embodiment.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

When one element is identified as “coupled” to another element, the elements may be coupled directly or through at least one intervening element between the elements. When two elements are identified as “directly coupled,” one element is directly coupled to the other element without an intervening element between the two elements.

A semiconductor apparatus detects the duty cycle of the internal clock signals and adjusts the duty cycle of the internal clock signals when duty distortion is present, thereby improving operation of the semiconductor apparatus.

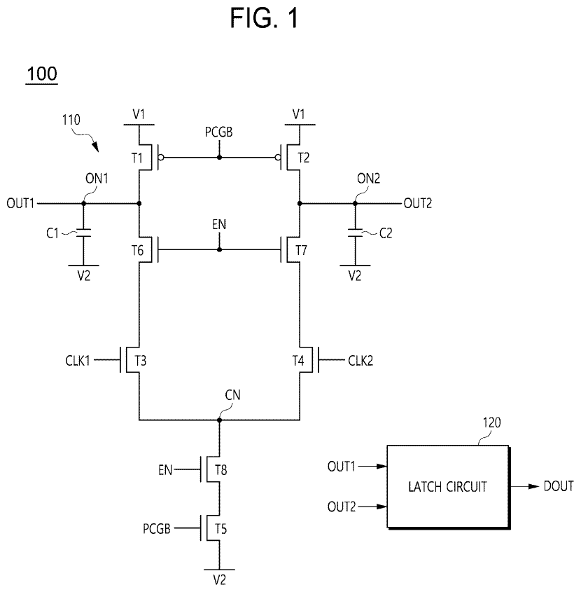

FIG. 1 is a diagram illustrating a configuration of a duty cycle monitoring circuit 100 according to an embodiment. Referring to FIG. 1, the duty cycle monitoring circuit 100 receives a first clock signal CLK1 and a second clock signal CLK2 and generates a duty detection signal DOUT based on the clock signals CLK1 and CLK2. The duty cycle monitoring circuit 100 generates a duty detection signal DOUT by comparing a duty cycle of the first clock signal CLK1 with a duty cycle of the second clock signal CLK2. For example, the duty cycle monitoring circuit 100 generates the duty detection signal DOUT by detecting the duty cycle of the first clock signal CLK1 with respect to the duty cycle of the second clock signal CLK2. The second clock signal CLK2 may be a complementary clock signal having a phase opposite to the phase of the first clock signal CLK1. The duty cycle monitoring circuit 100 may generate the duty detection signal DOUT that is at a first logic level when the duty cycle of the first clock signal CLK1 is greater than the duty cycle of the second clock signal CLK2. The duty cycle monitoring circuit 100 may generate the duty detection signal DOUT that is at a second logic level when the duty cycle of the first clock signal CLK1 is less than the duty cycle of the second clock signal CLK2.

The duty cycle monitoring circuit 100 includes a duty cycle detection circuit 110 and a latch circuit 120. The duty cycle detection circuit 110 receives the clock signals CLK1 and CLK2 and generates a first output signal OUT1 and a second output signal OUT2 and detects the duty cycles of the clock signals CLK1 and CLK2. The duty cycle detection circuit 110 generates the first output signal OUT1 based on the duty cycle of the first clock signal CLK1. The duty cycle detection circuit 110 generates the second output signal OUT2 based on the duty cycle of the second clock signal CLK2. The duty cycle detection circuit 110 generates the first output signal OUT1 at a lower voltage level as the duty cycle of the first clock signal CLK1 increases and generates the first output signal OUT1 at a higher voltage level as the duty cycle of the first clock signal CLK1 decreases. The duty cycle detection circuit 110 generates the second output signal OUT2 at a lower voltage level as the duty cycle of the second clock signal CLK2 increases and generates the second output signal OUT2 at a higher voltage level as the duty cycle of the second clock signal CLK2 decreases. When the duty cycle of the first clock signal CLK1 is greater than the duty cycle of the second clock signal CLK2, the duty cycle detection circuit 110 generates the first output signal OUT1 at a voltage level lower than the voltage level of the second output signal OUT2. When the duty cycle of the first clock signal CLK1 is less than the duty cycle of the second clock signal CLK2, the duty cycle detection circuit 110 generates the first output signal OUT1 at a voltage level higher than the voltage level of the second output signal OUT2. The duty cycle detection circuit 110 provides the output signals OUT1 and OUT2 to the latch circuit 120.

The latch circuit 120 receives the output signals OUT1 and OUT2 and generates the duty detection signal DOUT based on the output signals OUT1 and OUT2. The latch circuit 120 generates the duty detection signal DOUT when one of the output signals OUT1 or OUT2 reaches a trigger voltage. For example, when the first output signal OUT1 is lowered to the trigger voltage before the second output signal OUT2 reaches the trigger voltage, the latch circuit 120 generates the duty detection signal DOUT at the first logic level. When the second output signal OUT2 is lowered to the trigger voltage before the first output signal OUT1 reaches the trigger voltage, the latch circuit 120 generates the duty detection signal DOUT at the second logic level. The trigger voltage may be at one of various voltage levels. For example, the trigger voltage is at a voltage level corresponding to 50% or less of a maximum voltage level of the output signal OUT1 or OUT2, but is not limited to this example. The latch circuit 120 includes a Schmitt trigger latch circuit configured to adjust the voltage level of the trigger voltage and to trigger the logic level of the duty detection signal DOUT when one of the output signals OUT1 or OUT2 reaches the voltage level of the trigger voltage in this example.

The duty cycle detection circuit 110 includes a first transistor T1, a second transistor T2, a third transistor T3, a fourth transistor T4, a fifth transistor T5, a first capacitor C1, and a second capacitor C2. The transistors T1 and T2 may each be a P-channel metal-oxide-semiconductor (MOS) transistor. A gate of the first transistor T1 receives a precharge signal PCGB. A source of the first transistor T1 is electrically coupled to a terminal to which a first power supply voltage V1 is supplied. A drain of the first transistor T1 is electrically coupled to a first output node ON1. The first output signal OUT1 may be output from the first output node ON1. A gate of the second transistor T2 receives the precharge signal PCGB. A source of the second transistor T2 is electrically coupled to a terminal to which the first power supply voltage V1 is supplied. A drain of the second transistor T2 is electrically coupled to a second output node ON2. The second output signal OUT2 is output at the second output node ON2. The maximum voltage levels of the output signals OUT1 and OUT2 may be substantially the same as the voltage level of the first power supply voltage V1. The transistors T3, T4, and T5 may each be an N-channel MOS transistor. A gate of the third transistor T3 receives the first clock signal CLK1. A drain of the third transistor T3 is electrically coupled to the first output node ON1. A source of the third transistor T3 is electrically coupled to a common node CN. A gate of the fourth transistor T4 receives the second clock signal CLK2. A drain of the fourth transistor T4 is electrically coupled to the second output node ON2. A source of the fourth transistor T4 is electrically coupled to the common node CN. A gate of the fifth transistor T5 may receive the precharge signal PCGB. A drain of the fifth transistor T5 is electrically coupled to the common node CN. A source of the fifth transistor T5 is electrically coupled to a terminal to which a second power supply voltage V2 is supplied. The second power supply voltage V2 is at a voltage level lower than the first power supply voltage V1. One end of the first capacitor C1 is electrically coupled to the first output node ON1. The other end of the first capacitor C2 is electrically coupled to the terminal to which the second power supply voltage V2 is supplied. One end of the second capacitor C2 is electrically coupled to the second output node ON2. The other end of the second capacitor C2 is electrically coupled to the terminal to which the second power supply voltage V2 is supplied. The duty cycle detection circuit 110 generates the first output signal OUT1 by discharging the first capacitor C1 that is electrically coupled to the first output node ON1 for a time corresponding to a pulse width of the first clock signal CLK1. The duty cycle detection circuit 110 generates the second output signal OUT2 by discharging the second capacitor C2 that is electrically coupled to the second output node ON2 for a time corresponding to a pulse width of the second clock signal CLK2.

When the precharge signal PCGB is enabled at a low logic level, the transistors T1 and T2 are turned on, and the transistors T3, T4, and T5 are turned off. The first transistor T1 supplies the first power supply voltage V1 to the first output node ON1, and the second transistor T2 supplies the first power supply voltage V1 to the second output node ON2. As the first power supply voltage V1 is supplied to the output nodes ON1 and ON2, the capacitors C1 and C2 are charged. The output nodes ON1 and ON2 are precharged at a voltage level corresponding to the voltage level of the first power supply voltage V1. When the precharge signal PCGB is disabled at a high logic level, the transistors T1 and T2 are turned off, and the transistors T3, T4, and T5 are turned on. The fifth transistor T5 activates a current path from the common node CN to the terminal to which the second power supply voltage V2 is supplied. The third transistor T3 sinks current from the first output node ON1 to the common node CN during a period when the pulse of the first clock signal CLK1 is enabled during each cycle of the first clock signal CLK1, thereby discharging the first capacitor C1 and lowering the voltage level of the first output node ON1. The fourth transistor T4 sinks current from the second output node ON2 to the common node CN during a period when the pulse of the second clock signal CLK2 is enabled during each cycle of the second clock signal CLK2, thereby discharging the second capacitor C2 and lowering the voltage level of the second output node ON2.

The duty cycle detection circuit 110 includes a sixth transistor T6, a seventh transistor T7, and an eighth transistor T8. The transistors T6 and T7 may each be a P-channel MOS transistor. The sixth transistor T6 is electrically coupled between the first output node ON1 and the third transistor T3. A gate of the sixth transistor T6 receives an enable signal EN. A drain of the sixth transistor T6 is electrically coupled to the first output node ON1. A source of the sixth transistor T6 is electrically coupled to the drain of the third transistor T3. The seventh transistor T7 is electrically coupled between the second output node ON2 and the fourth transistor T4. A gate of the seventh transistor T7 receives the enable signal EN. A drain of the seventh transistor T7 is electrically coupled to the second output node ON2. A source of the seventh transistor T7 is electrically coupled to the drain of the fourth transistor T4. When the enable signal EN is disabled at a low logic level, the transistors T6 and T7 electrically couple the output nodes ON1 and ON2 to equalize the voltage levels of the output nodes ON1 and ON2, respectively. When the enable signal EN is enabled at a high logic level, the transistors T6 and T7 electrically decouple the output nodes ON1 and ON2. The eighth transistor T8 may be an N-channel MOS transistor. The eighth transistor T8 is electrically coupled between the common node CN and the fifth transistor T5. A gate of the eighth transistor T8 receives the enable signal EN. A drain of the eighth transistor T8 is electrically coupled to the common node CN. A source of the eighth transistor T8 is electrically coupled to the drain of the fifth transistor T5. When the enable signal EN is enabled, the eighth transistor T8 activates a current path between the common node CN and the fifth transistor T5. In an embodiment, the eighth transistor T8 is electrically coupled between the fifth transistor T5 and the terminal to which the second power supply voltage V2 is supplied. The enable signal EN is a signal that enables or triggers the duty cycle monitoring circuit 100 to perform a duty monitoring operation. The enable signal EN remains in an enabled state throughout a period during which the duty cycle monitoring circuit 100 performs the duty monitoring operation. The precharge signal PCGB is enabled for a predetermined time period when the enable signal EN is enabled. The precharge signal PCGB is disabled after the predetermined time period elapses. The predetermined time period may be a time period sufficient for the capacitors C1 and C2 to be charged to a voltage level corresponding to the voltage level of the first power supply voltage V1. In an embodiment, the precharge signal PCGB is periodically enabled while the enable signal EN remains enabled. For example, the precharge signal PCGB is enabled again after a sufficient time has passed following the generation of the duty detection signal DOUT by the latch circuit 120.

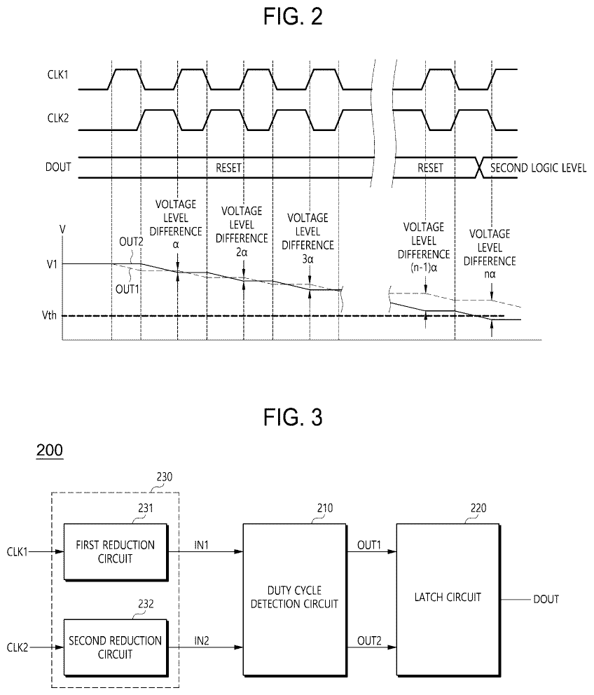

FIG. 2 is a timing diagram during operation of the duty cycle monitoring circuit 100 according to an embodiment. Referring to FIG. 1 and FIG. 2, operation of the duty cycle monitoring circuit 100 according to an embodiment is described. A vertical axis of a graph illustrated in FIG. 2 represents voltage V. The capacitors C1 and C2 are in a precharged state, and the voltage levels of the output signals OUT1 and OUT2 are at the voltage level of the first power supply voltage V1. In FIG. 2, the duty cycle of the second clock signal CLK2 is greater than the duty cycle of the first clock signal CLK1. When a first cycle of the clock signals CLK1 and CLK2 elapses, the voltage levels of the output signals OUT1 and OUT2 decrease in accordance with the pulse widths of the clock signals CLK1 and CLK2, respectively. Because the pulse width of the second clock signal CLK2 is greater than the pulse width of the first clock signal CLK1, the voltage level of the second output signal OUT2 is lower than the voltage level of the first output signal OUT1. For example, the second output signal OUT2 has a voltage level lower byα than the voltage level of the first output signal OUT1. As each cycle of the clock signals CLK1 and CLK2 progresses, the voltage level difference between the second output signal OUT2 and the first output signal OUT1 increases by a multiple of the quantity of elapsed cycles. When a second cycle of the clock signals CLK1 and CLK2 elapses, the voltage level difference between the output signals OUT1 and OUT2 is 2α. When a third cycle of the clock signals CLK1 and CLK2 elapses, the voltage level difference between the output signals OUT1 and OUT2 is 3α. When an (n−1) cycle of the clock signals CLK1 and CLK2 elapses, the voltage level difference between the output signals OUT1 and OUT2 is (n−1)α. When an nth cycle of the clock signals CLK1 and CLK2 elapses, the voltage level difference between the output signals OUT1 and OUT2 is nα. For example, n is an integer greater than or equal to 5. When the nth cycle of the clock signals CLK1 and CLK2 elapses, the voltage level of the second output signal OUT2 decreases to a level equal at or lower than the voltage level of the trigger voltage Vth. The latch circuit 120 detects that the voltage level of the second output signal OUT2 decreases to a level equal to or lower than the voltage level of the trigger voltage Vth and triggers the logic level of the duty detection signal DOUT at an activation level. The latch circuit 120 outputs the duty detection signal DOUT in a reset state RESET and when the voltage level of the second output signal OUT2 is lower than the voltage level of the trigger voltage Vth, outputs the duty detection signal DOUT at the second logic level. When the duty cycles of both the clock signals CLK1 and CLK2 are relatively large, the duty cycle monitoring circuit 100 may fail to accurately generate the duty detection signal DOUT, and a difference between the duty cycles of the clock signals CLK1 and CLK2 may not be significant. When the frequencies of the clock signals CLK1 and CLK2 are relatively low, the duty cycle monitoring circuit 100 may fail to accurately generate the duty detection signal DOUT. Because the second clock signal CLK2 has a phase opposite to the phase of the first clock signal CLK1, during a first half-cycle of one period, the voltage level of the first output signal OUT1 first decreases according to the pulse width of the first clock signal CLK1. During a latter half-cycle, the voltage level of the second output signal OUT2 decreases according to the pulse width of the second clock signal CLK2. When both the clock signals CLK1 and CLK2 have relatively large duty cycles and the difference in the duty cycles of the clock signals CLK1 and CLK2 is not significant, such as when the duty cycle of the second clock signal CLK2 is slightly larger than the duty cycle of the first clock signal CLK1, the first output signal OUT1 reaches the trigger voltage Vth before the second output signal OUT2. Due to an offset present in the latch circuit 120, a malfunction may occur during which the first output signal OUT1 reaches the trigger voltage Vth before the second output signal OUT2. When the duty cycles of both the clock signals CLK1 and CLK2 are excessively large, or when the frequencies are excessively small, the pulse widths of the clock signals CLK1 and CLK2 become large. Accordingly, one of the output signals OUT1 and OUT2 reaches the trigger voltage without a significant voltage level difference between output signals OUT1 and OUT2. To prevent such a malfunction, the duty cycles of the clock signals CLK1 and CLK2 are reduced before performing the duty monitoring operation.

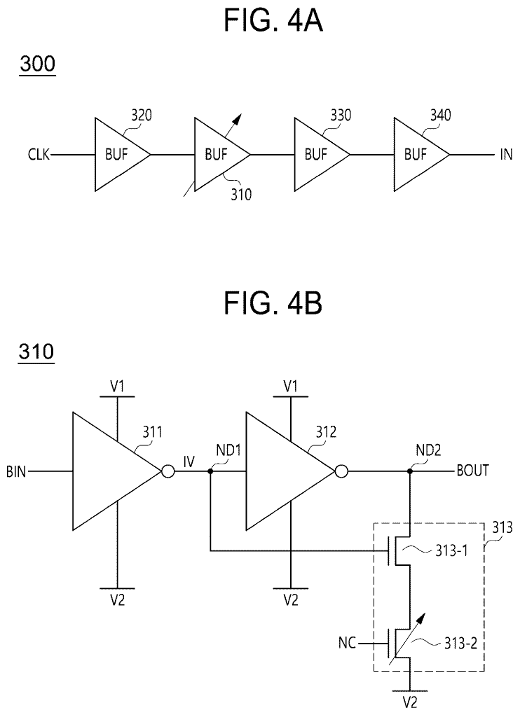

FIG. 3 is a diagram illustrating a configuration of a duty cycle monitoring circuit 200 according to an embodiment. Referring to FIG. 3, the duty cycle monitoring circuit 200 receives a first clock signal CLK1 and a second clock signal CLK2 and generates a duty detection signal DOUT by comparing duty cycles of the clock signals CLK1 and CLK2. The second clock signal CLK2 may be a complementary clock signal having a phase opposite to the phase of the first clock signal CLK1. The duty cycle monitoring circuit 200 reduces the duty cycles of both the clock signals CLK1 and CLK2 by the same period of time and may accurately generate the duty detection signal DOUT by comparing the duty cycles of the clock signals having reduced duty cycles. The duty cycle monitoring circuit 200 includes a duty cycle reduction circuit 230, a duty cycle detection circuit 210, and a latch circuit 220.

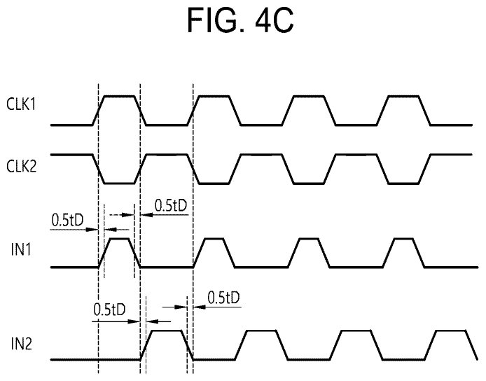

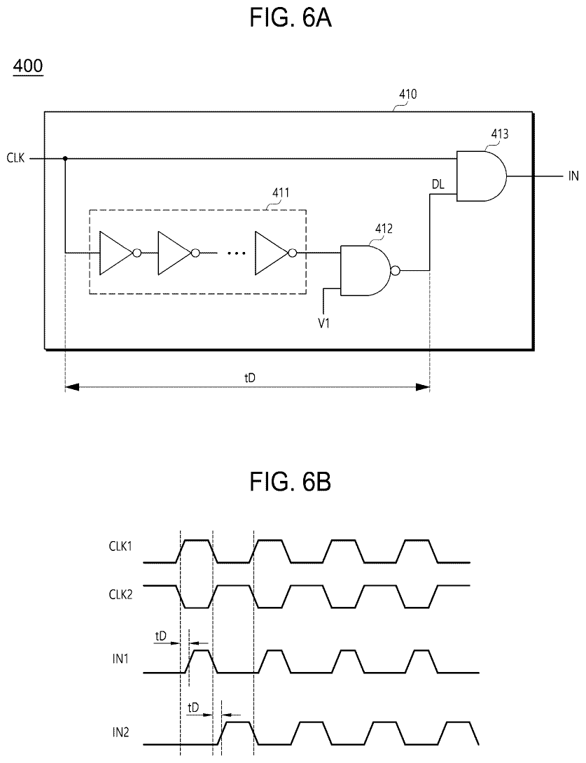

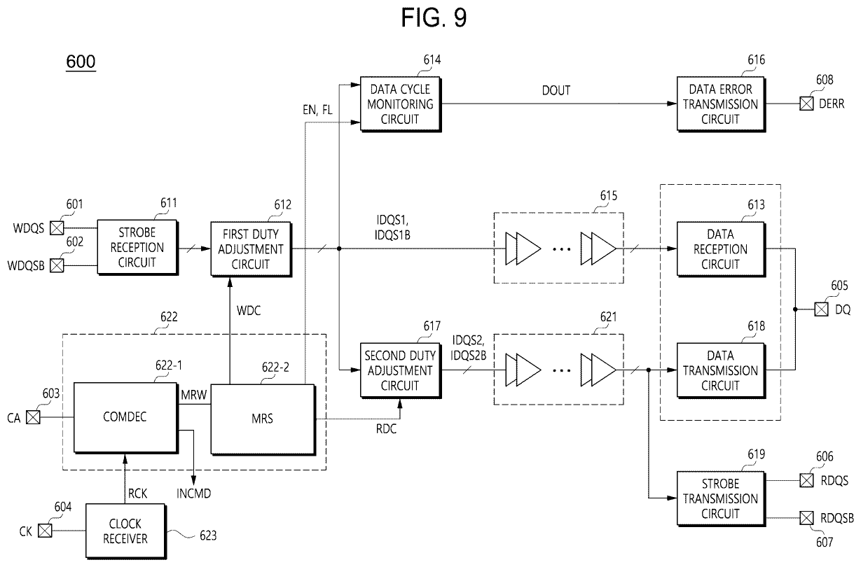

The duty cycle reduction circuit 230 receives the clock signals CLK1 and CLK2 and generates a first input signal IN1 and a second input signal IN2. The duty cycle reduction circuit 230 generates the input signals IN1 and IN2 by reducing the duty cycle of each of the clock signals CLK1 and CLK2 by the same period of time. The duty cycle reduction circuit 230 decreases the pulse widths of the clock signals CLK1 and CLK2 by the same period of time, thereby reducing the duty cycles of the clock signals CLK1 and CLK2. The duty cycle reduction circuit 230 generates the first input signal IN1 by reducing the duty cycle of the first clock signal CLK1 by a predetermined amount, such that the first input signal IN1 has a duty cycle reduced by the predetermined amount compared to the duty cycle of the first clock signal CLK1. The duty cycle reduction circuit 230 generates the second input signal IN2 by reducing the duty cycle of the second clock signal CLK2 by the predetermined amount, such that the second input signal IN2 has a duty cycle reduced by the predetermined amount compared to the duty cycle of the second clock signal CLK2. The predetermined amount may have various different values that may vary based on a control signal, for example, as described with respect to FIG. 4B, FIG. 6A, or FIG. 9.

The duty cycle reduction circuit 230 includes a first reduction circuit 231 and a second reduction circuit 232. The first reduction circuit 231 receives the first clock signal CLK1 and generates the first input signal IN1 by reducing the duty cycle of the first clock signal CLK1 by the predetermined amount. The first reduction circuit 231 adjusts the pulse width of the first clock signal CLK1 to generate the first input signal IN1 with a duty cycle different from the duty cycle of the first clock signal CLK1. The first reduction circuit 231 decreases the pulse width of the first clock signal CLK1 to generate the first input signal IN1 with a smaller duty cycle than the duty cycle of the first clock signal CLK1. The second reduction circuit 232 receives the second clock signal CLK2 and generates the second input signal IN2 by reducing the duty cycle of the second clock signal CLK2 by the predetermined amount. The second reduction circuit 232 adjusts the pulse width of the second clock signal CLK2 to generate the second input signal IN2 with a duty cycle different from the duty cycle of the second clock signal CLK2. The second reduction circuit 232 decreases the pulse width of the second clock signal CLK2 to generate the second input signal IN2 with a smaller duty cycle than the duty cycle of the second clock signal CLK2. The duty cycle reduction circuit 230 provide the input signals IN1 and IN2 to the duty cycle detection circuit 210.

The duty cycle detection circuit 210 receives the input signals IN1 and IN2 and generates a first output signal OUT1 and a second output signal OUT2 by comparing the duty cycles of the input signals IN1 and IN2. The duty cycle detection circuit 210 may have a configuration substantially similar to the configuration of the duty cycle detection circuit 110 illustrated in FIG. 1 and may perform substantially the same functions. The latch circuit 220 receives the output signals OUT1 and OUT2 and generates the duty cycle detection signal DOUT. The latch circuit 220 may have a configuration substantially similar to the configuration of the latch circuit 120 illustrated in FIG. 1 and may perform substantially the same functions.

FIG. 4A is a diagram illustrating a configuration of a reduction circuit 300 according to an embodiment. Referring to FIG. 4A, the reduction circuit 300 includes at least a first buffer circuit 310. The first buffer circuit 310, as shown in FIG. 4B, generates the input signal IN by buffering the clock signal CLK. A threshold voltage of the first buffer circuit 310 is at a voltage level higher than an intermediate voltage of a swing range of the clock signal CLK. The first buffer circuit 310, using the threshold voltage at a voltage level higher than the intermediate voltage, generates the input signal IN with a pulse width reduced compared to the pulse width of the clock signal CLK. The reduction circuit 300 includes a second buffer circuit 320, a third buffer circuit 330, and a fourth buffer circuit 340. The second buffer circuit 320 is disposed as a stage preceding the first buffer circuit 310, and the buffer circuits 330 and 340 are sequentially disposed as subsequent stages of the first buffer circuit 310. Threshold voltages of the buffer circuits 320, 330, and 340 are at voltage levels that are substantially similar to the intermediate voltage. Accordingly, the buffer circuits 320, 330, and 340 generate output signals having the same duty cycle characteristics as the input signals. The second buffer circuit 320 receives the clock signal CLK and buffers the clock signal CLK. The output signal of the second buffer circuit 320 has a duty cycle that is substantially identical to the duty cycle of the clock signal CLK. The first buffer circuit 310 receives the output signal of the second buffer circuit 320 and generates an output signal with a duty cycle reduced compared to the duty cycle of the output signal of the second buffer circuit 320. The third buffer circuit 330 receives the output signal of the first buffer circuit 310 and generates an output signal with a duty cycle that is substantially similar to the duty cycle of the output signal of the first buffer circuit 310. The fourth buffer circuit 340 receives the output signal of the third buffer circuit 330 and generates an input signal IN with a duty cycle that is substantially similar to the duty cycle of the output signal of the third buffer circuit 330. Although FIG. 4A illustrates the first buffer circuit 310 at a second stage of the reduction circuit 300, the first buffer circuit 310 may be located at any of the first through fourth stages.

Referring to FIG. 4B, the first buffer circuit 310 includes a first inverter 311, a second inverter 312, and a threshold voltage regulator 313. The first buffer circuit 310 receives a first power supply voltage V1 and a second power supply voltage V2 and operates using the power supply voltages V1 and V2. The power supply voltages V1 and V2 may be substantially identical to the power supply voltages V1 and V2 in FIG. 1. The first inverter 311 receives a buffer input signal BIN, the output signal of the second buffer circuit 320, inverts the buffer input signal BIN, and outputs an inverted signal IV at a first node ND1. The second inverter 312 receives the inverted signal IV, inverts the inverted signal IV, and outputs a buffer output signal BOUT, the output signal of the first buffer circuit 310, at a second node ND2. The threshold voltage regulator 313 receives the inverted signal IV and a threshold control signal NC. The threshold voltage regulator 313 pull-down drives the voltage at the second node ND2 based on the inverted signal IV and the threshold control signal NC. The threshold voltage regulator 313 adjusts drive strength that pull-down drives the voltage at the second node ND2 based on the threshold control signal NC. The threshold voltage regulator 313 includes a first transistor 313-1 and a second transistor 313-2. The transistors 313-1 and 313-2 may each include an N-channel MOS transistor. A gate of the first transistor 313-1 receives the inverted signal IV, and a drain of the first transistor 313-1 is electrically coupled to the second node ND2. A gate of the second transistor 313-2 receives the threshold control signal NC. A drain of the second transistor 313-2 is electrically coupled to the source of the first transistor 313-1. A source of the second transistor 313-2 is electrically coupled to a terminal to which the second power supply voltage V2 is supplied. In an embodiment, the threshold control signal NC is an analog signal and current drive strength of the second transistor 313-2 varies depending on the voltage level of the threshold control signal NC. In an embodiment, the threshold control signal NC is a digital signal, and the second transistor 313-2 is implemented with a plurality of transistors that are electrically coupled in parallel. The plurality of transistors varies the current drive strength of the threshold voltage regulator 313 in response to each bit of the threshold control signal NC. When the inverted signal IV is at a low logic level, the first transistor 313-1 is turned off, and the threshold voltage regulator 313 does not affect the voltage level of the buffer output signal BOUT. When the inverted signal IV is at a high logic level, the first transistor 313-1 is turned on, and the threshold voltage regulator 313 lowers the voltage level of the buffer output signal BOUT. The threshold voltage regulator 313 increases pull-down drive strength of the first buffer circuit 310 compared to pull-up drive strength, thereby performing a function including raising the threshold voltage of the first buffer circuit 310. The reduction circuits 231 and 232 illustrated in FIG. 3 may each have a configuration that is substantially similar to the configuration of the reduction circuit 300 and may perform substantially the same functions. The first reduction circuit 231 and the second reduction circuit 232 may be implemented similarly to the reduction circuit 300 with the first clock signal CLK1 and the second clock signal CLK2 as inputs and the first input signal IN1 and the second input signal IN2 as outputs, respectively.

FIG. 4C is a timing diagram during operation of the duty cycle reduction circuit 230, for example, as illustrated in FIG. 3. The reduction circuits 231 and 232 of the duty cycle reduction circuit 230 are configured with the configuration of the reduction circuit 300 illustrated in FIG. 4A. Referring to FIG. 3, FIG. 4A, FIG. 4B, and FIG. 4C, the first reduction circuit 231 buffers the first clock signal CLK1, adjusts the pulse width of the first clock signal CLK1, and generates the first input signal IN1. The first reduction circuit 231 uses a buffer circuit with a threshold voltage at a voltage level higher than an intermediate voltage of a swing range of the first clock signal CLK1 to buffer the first clock signal CLK1. The first input signal IN1 is generated with a smaller duty cycle and/or pulse width than the duty cycle of the first clock signal CLK1. The second reduction circuit 232 buffers the second clock signal CLK2, adjusts the pulse width of the second clock signal CLK2, and generates the second input signal IN2. A rising edge of the first input signal IN1 is generated 0.5 tD later than a rising edge of the first clock signal CLK1, and a falling edge of the first input signal IN1 is generated 0.5 tD earlier than a falling edge of the first clock signal CLK1. The value of tD varies depending on the value of the threshold control signal NC. The second reduction circuit 232 uses a buffer circuit with a threshold voltage at a voltage level higher than an intermediate voltage of a swing range of the second clock signal CLK2 to buffer the second clock signal CLK2. The second input signal IN2 is generated with a smaller duty cycle and/or pulse width than the duty cycle of the second clock signal CLK2. A rising edge of the second input signal IN2 is generated 0.5tD later than a rising edge of the second clock signal CLK2, and a falling edge of the second input signal IN2 is generated 0.5 tD earlier than a falling edge of the second clock signal CLK2. Accordingly, the duty cycle reduction circuit 230 decreases the pulse widths of the clock signals CLK1 and CLK2 by tD, thereby reducing the respective duty cycles of the clock signals CLK1 and CLK2 by the same period of time and generating the input signals IN1 and IN2.

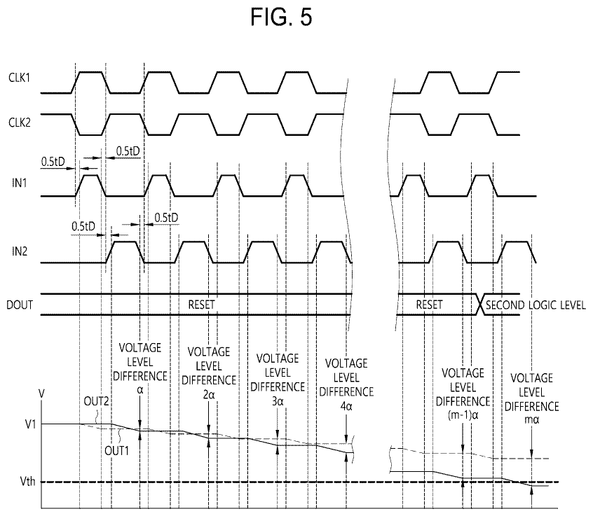

FIG. 5 is a timing diagram during operation of the duty cycle monitoring circuit 200 according to an embodiment. Referring to FIG. 3 to FIG. 5, the operation of the duty cycle monitoring circuit 200 according to an embodiment is described. The duty cycle reduction circuit 230 receives the clock signals CLK1 and CLK2 and generates the input signals IN1 and IN2 by reducing the duty cycles of the clock signals CLK1 and CLK2 by the same period of time. When the first reduction circuit 231 and the second reduction circuit 232 are implemented with the reduction circuit 300 of FIG. 4A, the rising edge of the first input signal IN1 is generated 0.5 tD later than the rising edge of the first clock signal CLK1, and the falling edge of the first input signal IN1 is generated 0.5 tD earlier than the falling edge of the first clock signal CLK1. The rising edge of the second input signal IN2 is generated 0.5 tD later than the rising edge of the second clock signal CLK2, and the falling edge of the second input signal IN2 is generated 0.5 tD earlier than the falling edge of the second clock signal CLK2. The input signals IN1 and IN2 each have a pulse width reduced by time period tD compared to the clock signals CLK1 and CLK2, respectively. Because the duty cycle reduction circuit 230 reduces the duty cycles of the clock signals CLK1 and CLK2 by the same period of time, a duty cycle difference between the input signals IN1 and IN2 is substantially similar to a duty cycle difference between the clock signals CLK1 and CLK2.

The duty cycle detection circuit 210 receives the input signals IN1 and IN2 and detects the duty cycles of the input signals IN1 and IN2. A vertical axis of the timing diagram in FIG. 5 represents voltage V. When the capacitors of the duty cycle detection circuit 210 are in a precharged state, the voltage levels of the output signals OUT1 and OUT2 correspond to the voltage level of the first power supply voltage V1. In FIG. 5, the duty cycle of the second clock signal CLK2 is greater than the duty cycle of the first clock signal CLK1. When a first cycle of the clock signals CLK1 and CLK2 elapses, the voltage levels of the output signals OUT1 and OUT2 decreases in accordance with the pulse widths of the input signals IN1 and IN2, respectively. Because the pulse width of the second input signal IN2 is greater than the pulse width of the first input signal IN1, the voltage level of the second output signal OUT2 is lower than the voltage level of the first output signal OUT1. For example, the second output signal OUT2 is at a voltage level lower by α than the voltage of the first output signal OUT1. As each cycle of the clock signals CLK1 and CLK2 progresses, the voltage level difference between the second output signal OUT2 and the first output signal OUT1 increases by a multiple of the quantity of elapsed cycles. When a second cycle of the clock signals CLK1 and CLK2 elapses, the voltage level difference between the output signals OUT1 and OUT2 is 2α. When a third cycle of the clock signals CLK1 and CLK2 elapses, the voltage level difference between the output signals OUT1 and OUT2 is 3α. When an (m−1) cycle of the clock signals CLK1 and CLK2 elapses,the voltage level difference between the output signals OUT1 and OUT2 is (m−1)α. When an mth cycle of the clock signals CLK1 and CLK2 elapses, the voltage level difference between the output signals OUT1 and OUT2 is mα. For example, m is an integer greater than or equal to 6. The amount by which the voltage level of the first output signal OUT1 decreases in response to the first input signal IN1 is less than the amount by which the voltage level of the first output signal OUT1 decreases in response to the first clock signal CLK1. The amount by which the voltage level of the second output signal OUT2 decreases in response to the second input signal IN2 is less than the amount by which the voltage level of the second output signal OUT2 decreases in response to the second clock signal CLK2. A rate at which the voltage levels of the output signals OUT1 and OUT2 decrease, as shown in FIG. 5, is less than a rate at which the voltage levels of the output signals OUT1 and OUT2 decrease, as shown in FIG. 2. When the duty cycle detection circuit 210 detects the duty cycles of the input signals IN1 and IN2, which have reduced duty cycles compared to the clock signals CLK1 and CLK2, the time for the output signals OUT1 and OUT2 to reach the trigger voltage Vth of the latch circuit 220 increases. Thus, the quantity of cycles of the clock signals CLK1 and CLK2 that elapse for the output signals OUT1 and OUT2 to reach the trigger voltage Vth increases.

When the mth cycle of the clock signals CLK1 and CLK2 elapses, the voltage level of the second output signal OUT2 is lowered to a level equal to or lower than the voltage level of the trigger voltage Vth. The latch circuit 220 outputs the duty detection signal DOUT in a reset state RESET, and upon detecting that the voltage level of the second output signal OUT2 decreases to a level equal to or lower than the voltage level of the trigger voltage Vth, triggers the logic level of the duty detection signal DOUT at an activation level. The latch circuit 220 outputs the duty detection signal DOUT at a second logic level when the voltage level of the second output signal OUT2 becomes lower than the voltage level of the trigger voltage Vth. The duty cycle monitoring circuit 200 compares the duty cycles of the input signals IN1 and IN2, which have reduced duty cycles and increases the quantity of cycles of the clock signals CLK1 and CLK2 for one of the first output signal OUT1 and the second output signal OUT2 to reach the trigger voltage Vth. Therefore, when one of the first output signal OUT1 and the second output signal OUT2 reaches the trigger voltage Vth, the voltage level difference between the first output signal OUT1 and the second output signal OUT2 becomes larger. For example, in FIG. 2, the voltage level difference between the output signals OUT1 and OUT2 is nα, whereas, in FIG. 5, the voltage level difference between the output signals OUT1 and OUT2 is mα. When the latch circuit 220 is triggered, a larger voltage level difference between the output signals OUT1 and OUT2 mitigates and/or prevents malfunctions during the duty monitoring operation. The duty cycle monitoring circuit 200 may accurately generate the duty detection signal corresponding to the duty cycle difference between the clock signals CLK1 and CLK2. A sufficiently large voltage level difference between the output signals OUT1 and OUT2 may mitigate and/or prevent instances where the duty detection signal DOUT is generated with an opposite logic level despite an offset in the latch circuit 220.

FIG. 6A is a diagram illustrating a configuration of an example of a reduction circuit 400 according to an embodiment. Referring to FIG. 6A, the reduction circuit 400 adjusts a pulse width of a clock signal CLK and generates an input signal IN. The reduction circuit 400 generates the input signal IN by delaying a point in time at which a rising edge of the clock signal CLK occurs. The reduction circuit 400 includes a pulse generator 410. The pulse generator 410 receives the clock signal CLK and generates the input signal IN by adjusting the pulse width of the clock signal CLK. The pulse generator 410 generates the input signal IN that has a rising edge occurring at a point in time later than the rising edge of the clock signal CLK and a falling edge occurring at the same point in time as the falling edge of the clock signal CLK. The pulse generator 410 includes an odd number of inverters 411, a NAND gate 412, and an AND gate 413. The odd number of inverters 411 is sequentially electrically coupled in series. The odd number of inverters 411 functions as a delay circuit. The inverter positioned at the first stage among the odd number of inverters 411 receives the clock signal CLK and outputs an inverted signal of the clock signal CLK. The inverter positioned at the last stage among the odd number of inverters 411 inverts an output signal of the preceding inverter and generate an output signal having a delayed phase and an opposite phase compared to the clock signal CLK. The NAND gate 412 receives the output signal of the last inverter among the odd number of inverters 411 and the first power supply voltage V1. The first power supply voltage V1 facilitates operation of the NAND gate 412 as an inverter. The first power supply voltage V1 is substantially the same as the first power supply voltage V1 utilized in FIG. 1. The NAND gate 412 inverts the output signal of the odd number of inverters 411 and generates a delayed output signal DL. In an embodiment, the NAND gate 412 is replaced with an inverter. The AND gate 413 receives the clock signal CLK and the delayed output signal DL and generates the input signal IN. The propagation delay caused by the odd number of inverters 411 and the NAND gate 412 may be variably set. To achieve the same performance as the reduction circuit 300 illustrated in FIG. 4A, the propagation delay is tD, as illustrated in FIG. 4C. The pulse generator 410 generates the input signal IN including a pulse that is enabled a time period tD later than the clock signal CLK and disabled at the same point in time as the clock signal CLK. The reduction circuits 231 and 232 illustrated in FIG. 3, may each have a configuration that is substantially similar to the configuration of the reduction circuit 400 and may perform substantially the same functions. The first reduction circuit 231 and the second reduction circuit 232 may be implemented similarly to the reduction circuit 400 with the first clock signal CLK1 and the second clock signal CLK2 as inputs and the first input signal IN1 and the second input signal IN2 as outputs, respectively.

FIG. 6B is a timing diagram during operation of the duty cycle reduction circuit 230, for example, as illustrated in FIG. 3. The duty cycle reduction circuit 230 utilizes the configuration of the reduction circuit 400 illustrated in FIG. 6A. Referring to FIG. 3, FIG. 6A, and FIG. 6B, the first reduction circuit 231 generates the first input signal IN1 by reducing the pulse width of the first clock signal CLK1. The rising edge of the first input signal IN1 is generated a time period tD later than the rising edge of the first clock signal CLK1. The falling edge of the first input signal IN1 is generated at the same point in time as the falling edge of the first clock signal CLK1. The second reduction circuit 232 generates the second input signal IN2 by reducing the pulse width of the second clock signal CLK2. The rising edge of the second input signal IN2 is generated a time period tD later than the rising edge of the second clock signal CLK2. The falling edge of the second input signal IN2 is generated at the same point in time as the falling edge of the second clock signal CLK2. The duty cycle reduction circuit decreases the pulse widths of the clock signals CLK1 and CLK2 by time period tD, thereby reducing the respective duty cycles of the clock signals CLK1 and CLK2 by the same time period tD and generating the input signals IN1 and IN2.

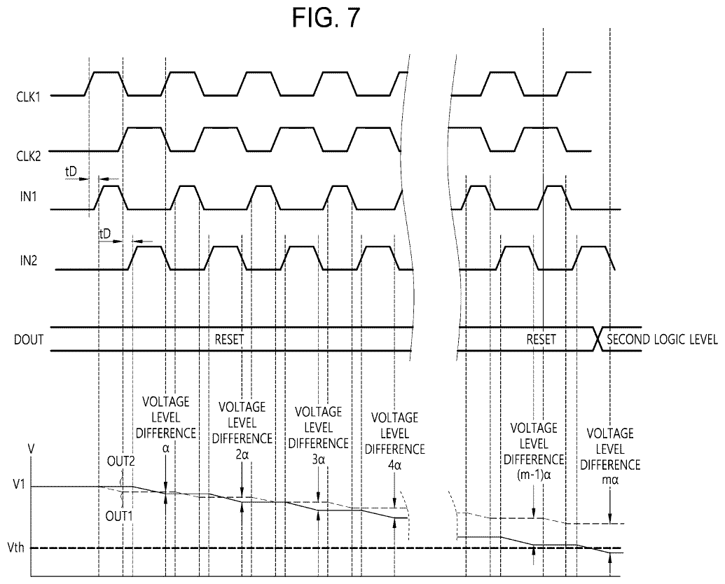

FIG. 7 is a timing diagram during operation of the duty cycle monitoring circuit 200 according to an embodiment. Referring to FIG. 3, FIG. 6A, FIG. 6B, and FIG. 7, the operation of the duty cycle monitoring circuit 200 according to an embodiment is described. The duty cycle reduction circuit 230 receives the clock signals CLK1 and CLK2 and generates the input signals IN1 and IN2 by reducing the duty cycles of the clock signals CLK1 and CLK2 by the same period of time. Wen the first reduction circuit 231 and the second reduction circuit 232 are implemented with the reduction circuit 400 of FIG. 6A, the rising edge of the first input signal IN1 is generated a time period tD later than the rising edge of the first clock signal CLK1, and the falling edge of the first input signal IN1 is generated at the same point in time as the falling edge of the first clock signal CLK1. The rising edge of the second input signal IN2 is generated a time period tD later than the rising edge of the second clock signal CLK2, and the falling edge of the second input signal IN2 is generated at the same point in time as the falling edge of the second clock signal CLK2. The input signals IN1 and IN2 each have a pulse width reduced by time period tD compared to the clock signals CLK1 and CLK2, respectively. Because the duty cycle reduction circuit 230 reduces the duty cycles of the clock signals CLK1 and CLK2 by the same period of time tD, a duty cycle difference between the input signals IN1 and IN2 is substantially similar to a duty cycle difference between the clock signals CLK1 and CLK2.

The duty cycle detection circuit 210 receives the input signals IN1 and IN2 and detects the duty cycles of the input signals IN1 and IN2. A vertical axis of the timing diagram in FIG. 7 represents voltage V. When the capacitors of the duty cycle detection circuit 210 are in a precharged state, the voltage levels of the output signals OUT1 and OUT2 correspond to the voltage level of the first power supply voltage V1. In FIG. 7, the duty cycle of the second clock signal CLK2 is greater than the duty cycle of the first clock signal CLK1. When a first cycle of the clock signals CLK1 and CLK2 elapses, the voltage levels of the output signals OUT1 and OUT2 decreases in accordance with the pulse widths of the input signals IN1 and IN2, respectively. Because the pulse width of the second input signal IN2 is greater than the pulse width of the first input signal IN1, the voltage level of the second output signal OUT2 is lower than the voltage level of the first output signal OUT1. For example, the second output signal OUT2 is at a voltage level lower by α than the voltage of the first output signal OUT1. As each cycle of the clock signals CLK1 and CLK2 progresses, the voltage level difference between the second output signal OUT2 and the first output signal OUT1 increases by a multiple of the quantity of elapsed cycles. When a second cycle of the clock signals CLK1 and CLK2 elapses, the voltage level difference between the output signals OUT1 and OUT2 is 2α. When a third cycle of the clock signals CLK1 and CLK2 elapses, the voltage level difference between the output signals OUT1 and OUT2 is 3α. When an (m−1) cycle of the clock signals CLK1 and CLK2 elapses, the voltage level difference between the output signals OUT1 and OUT2 is (m−1)α. When an mth cycle of the clock signals CLK1 and CLK2 elapses, the voltage level difference between the output signals OUT1 and OUT2 is mα. For example, m is an integer greater than or equal to 6. The amount by which the voltage level of the first output signal OUT1 decreases in response to the first input signal IN1 is less than the amount by which the voltage level of the first output signal OUT1 decreases in response to the first clock signal CLK1. The amount by which the voltage level of the second output signal OUT2 decreases in response to the second input signal IN2 is less than the amount by which the voltage level of the second output signal OUT2 decreases in response to the second clock signal CLK2. A rate at which the voltage levels of the output signals OUT1 and OUT2 decrease, as shown in FIG. 7, is less than a rate at which the voltage levels of the output signals OUT1 and OUT2 decrease, as shown in FIG. 2. When the duty cycle detection circuit 210 detects the duty cycles of the input signals IN1 and IN2, which have reduced duty cycles compared to the clock signals CLK1 and CLK2, the time for the output signals OUT1 and OUT2 to reach the trigger voltage Vth of the latch circuit 220 increases.

When the mth cycle of the clock signals CLK1 and CLK2 elapses, the voltage level of the second output signal OUT2 is lowered to a level equal to or lower than the voltage level of the trigger voltage Vth. The latch circuit 220 may output the duty detection signal DOUT in a reset state RESET, and upon detecting that the voltage level of the second output signal OUT2 decreases to a level equal to or lower than the voltage level of the trigger voltage Vth, triggers the logic level of the duty detection signal DOUT to an activation level. The latch circuit 220 outputs the duty detection signal DOUT at a second logic level when the voltage level of the second output signal OUT2 becomes lower than the voltage level of the trigger voltage Vth. The duty cycle monitoring circuit 200 compares the duty cycles of the input signals IN1 and IN2, which have reduced duty cycles and increases the quantity of cycles of the clock signals CLK1 and CLK2 for one of the first output signal OUT1 and the second output signal OUT2 to reach the trigger voltage Vth. Therefore, when one of the first output signal OUT1 and the second output signal OUT2 reaches the trigger voltage Vth, the voltage level difference between the first output signal OUT1 and the second output signal OUT2 becomes larger. For example, in FIG. 2, the voltage level difference between the output signals OUT1 and OUT2 is nα, whereas, in FIG. 7, the voltage level difference between the output signals OUT1 and OUT2 is mα. When the latch circuit 220 is triggered, a larger voltage level difference between the output signals OUT1 and OUT2 mitigates and/or prevents malfunctions during the duty monitoring operation. The duty cycle monitoring circuit 200 may accurately generate the duty detection signal DOUT corresponding to the duty cycle difference between the clock signals CLK1 and CLK2. A sufficiently large voltage level difference between the output signals OUT1 and OUT2 may mitigate and/or prevent instances where the duty detection signal DOUT is generated with an opposite logic level despite an offset in the latch circuit 220.

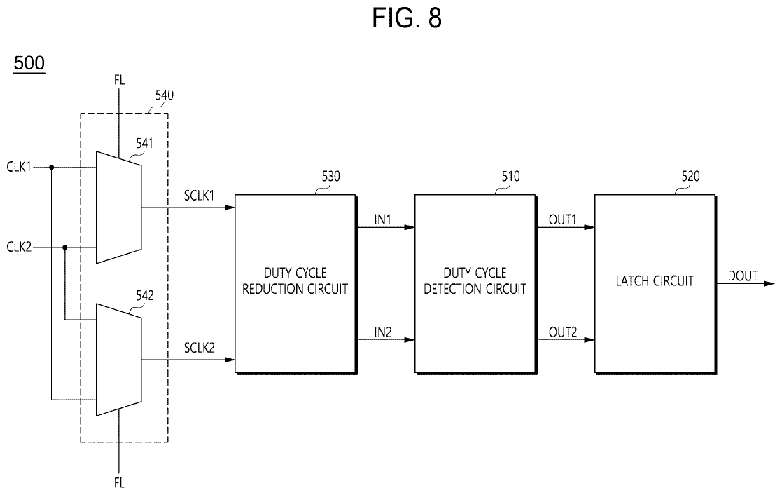

FIG. 8 is a diagram illustrating a configuration of a duty cycle monitoring circuit 500 according to an embodiment. Referring to FIG. 8, the duty cycle monitoring circuit 500 includes a clock chopper circuit 540, a duty cycle reduction circuit 530, a duty cycle detection circuit 510, and a latch circuit 520. The clock chopper circuit 540 receives a first clock signal CLK1, a second clock signal CLK2, and a flip signal FL and generates a first select clock signal SCLK1 and a second select clock signal SCLK2. Based on the flip signal FL, the clock chopper circuit 540 outputs one of the clock signals CLK1 and CLK2 as the first select clock signal SCLK1 and output the other of the clock signals CLK1 and CLK2 as the second select clock signal SCLK2. For example, when the flip signal FL is at a first logic level, the clock chopper circuit 540 outputs the first clock signal CLK1 as the first select clock signal SCLK1 and outputs the second clock signal CLK2 as the second select clock signal SCLK2. When the flip signal FL is at a second logic level, the clock chopper circuit 540 outputs the second clock signal CLK2 as the first select clock signal SCLK1 and outputs the first clock signal CLK1 as the second select clock signal SCLK2. The clock chopper circuit 540 switches the clock signals CLK1 and CLK2 based on the logic level of the flip signal FL and outputs the select clock signals SCLK1 and SCLK2. The clock chopper circuit 540 controls the duty cycle monitoring circuit 500 to generate the duty detection signal DOUT based on a detection result of the duty cycle of the first clock signal CLK1 relative to the duty cycle of the second clock signal CLK2 or to generate the duty detection signal DOUT based on a detection result of the duty cycle of the second clock signal CLK2 relative to the duty cycle of the first clock signal CLK1.

The duty cycle reduction circuit 530 receives the select clock signals SCLK1 and SCLK2 and generates a first input signal IN1 and a second input signal IN2 by reducing duty cycles of the select clock signals SCLK1 and SCLK2 by the same period of time. The duty cycle reduction circuit 530 may have a configuration substantially similar to the configuration of the duty cycle reduction circuit 230 illustrated in FIG. 3 and may perform substantially the same functions. The duty cycle detection circuit 510 receives the input signals IN1 and IN2 and generates a first output signal OUT1 and a second output signal OUT2 by detecting the duty cycles of the input signals IN1 and IN2. The latch circuit 520 receives the output signals OUT1 and OUT2 and generates the duty detection signal DOUT based on the output signals OUT1 and OUT2. The duty cycle detection circuit 510 and the latch circuit 520 may have configurations substantially similar to the configurations of the duty cycle detection circuit 210 and the latch circuit 220, respectively, of FIG. 3 and may perform functions substantially similar to the functions performed by the duty cycle detection circuit 210 and the latch circuit 220, respectively.

The clock chopper circuit 540 includes a first select circuit 541 and a second select circuit 542. The first select circuit 541 receives the first clock signal CLK1, the second clock signal CLK2, and the flip signal FL. When the flip signal FL is at a first logic level, the first select circuit 541 outputs the first clock signal CLK1 as the first select clock signal SCLK1. When the flip signal FL is at a second logic level, the first select circuit 541 outputs the second clock signal CLK2 as the first select clock signal SCLK1. The second select circuit 542 receives the first clock signal CLK1, the second clock signal CLK2, and the flip signal FL. When the flip signal FL is at the first logic level, the second select circuit 542 outputs the second clock signal CLK2 as the second select clock signal SCLK2. When the flip signal FL is at the second logic level, the second select circuit 542 outputs the first clock signal CLK1 as the second select clock signal SCLK2. The select circuits 541 and 542 may each be implemented with a 2-to-1 multiplexer.

The clock chopper circuit 540 may enhance the reliability of the duty monitoring operation of the duty cycle monitoring circuit 500. When the flip signal FL is at the first logic level, the clock chopper circuit 540 outputs the first clock signal CLK1 as the first select clock signal SCLK1 and outputs the second clock signal CLK2 as the second select clock signal SCLK2. The duty cycle monitoring circuit 500 detects the duty cycle of the first clock signal CLK1 relative to the duty cycle of the second clock signal CLK2. For example, when the duty cycle of the second clock signal CLK2 is greater than the duty cycle of the first clock signal CLK1, the duty cycle monitoring circuit 500 generates the duty detection signal DOUT at a first logic level. When the flip signal FL makes a transition from the first logic level to the second logic level, the clock chopper circuit 540 outputs the second clock signal CLK2 as the first select clock signal SCLK1 and outputs the first clock signal CLK1 as the second select clock signal SCLK2. The duty cycle monitoring circuit 500 detects the duty cycle of the second clock signal CLK2 relative to the duty cycle of the first clock signal CLK1. In this example, the duty cycle monitoring circuit 500 generates the duty detection signal DOUT at a second logic level. When the duty cycle monitoring circuit 500 generates the duty detection signal DOUT at the first logic level, the duty cycle difference between the clock signals CLK1 and CLK2 may be estimated or measured to be extremely small, an offset in the duty cycle monitoring circuit 500 may be detected, or a malfunction occurring in the duty cycle monitoring circuit 500 may be detected.

FIG. 9 is a diagram illustrating a configuration of a semiconductor apparatus 600 in accordance with an embodiment. The semiconductor apparatus 600 is electrically coupled to an external device through a plurality of pads, receives various signals from the external device, and transmits various signals to the external device. The semiconductor apparatus 600 receives a first strobe signal WDQS and a second strobe signal WDQSB from the external device through a first strobe pad 601 and a second strobe pad 602, respectively. The semiconductor apparatus 600 receives a command address signal CA from the external device through a command address pad 603. The command address signal CA includes a row command address signal and a column command address signal. The command address pad 603 includes a plurality of pads. The row command address signal and the column command address signal may be received through separate pads. The semiconductor apparatus 600 receives a system clock signal CK from the external device through a clock pad 604. The first strobe signals WDQS may have an opposite phase to the second strobe signal WDQSB. The strobe signals WDQS and WDQSB may operate at frequencies higher than the frequency of the system clock signal CK. For example, the frequencies of the strobe signals WDQS and WDQSB are twice the frequency of the system clock signal CK. In an embodiment, the frequencies of the strobe signals WDQS and WDQSB are equal to or lower than the frequency of the system clock signal CK. The semiconductor apparatus 600, through a data pad 605, receives data DQ transmitted from the external device and transmits the data DQ to the external device. The semiconductor apparatus 600 outputs a third strobe signal RDQS and a fourth strobe signal RDQSB to the external device through a third strobe pad 606 and a fourth strobe pad 607, respectively. The semiconductor apparatus 600 transmits a data error signal DERR to the external device through a data error pad 608. An operation in which the semiconductor apparatus 600 receives the data DQ from the external device may be a write operation. An operation in which the semiconductor apparatus 600 transmits the data DQ to the external device may be a read operation. The strobe signals WDQS and WDQSB may be write strobe signals, and the strobe signals RDQS and RDQSB may be read strobe signals. The strobe signals WDQS and WDQSB may be synchronized with the system clock signal CK and may be synchronized with the data DQ received by the semiconductor apparatus 600 from the external device. The strobe signals RDQS and RDQSB may be synchronized with the data DQ transmitted from the semiconductor apparatus 600 to the external device.

The semiconductor apparatus 600 includes a strobe reception circuit 611, a first duty adjustment circuit 612, a data reception circuit 613, and a duty cycle monitoring circuit 614. The strobe reception circuit 611 receives the strobe signals WDQS and WDQSB from the external device through the strobe pads 601 and 602. The strobe reception circuit 611 provides the strobe signals WDQS and WDQSB to the first duty adjustment circuit 612. The first duty adjustment circuit 612 receives a first duty control signal WDC. The first duty adjustment circuit 612 adjusts duty cycles of the strobe signals WDQS and WDQSB based on the first duty control signal WDC and generates a first internal strobe signal IDQS1 and a second internal strobe signal IDQS1B. The first duty adjustment circuit 612 adjusts the duty cycle of one or both of the strobe signals WDQS and WDQSB based on the first duty control signal WDC and generates the internal strobe signals IDQS1 and IDQS1B with adjusted duty cycles. The first duty control signal WDC is generated based on a result of the duty monitoring operation of the duty cycle monitoring circuit 614 and/or the duty detection signal DOUT. The data reception circuit 613 receives the internal strobe signals IDQS1 and IDQS1B. The data reception circuit 613 receives the data DQ from the external device through the data pad 605. The data reception circuit 613 receives the data DQ in synchronization with the internal strobe signals IDQS1 and IDQS1B. The data DQ received by the data reception circuit 613 is provided as an internal data signal of the semiconductor apparatus 600.

The duty cycle monitoring circuit 614 receives the internal strobe signals IDQS1 and IDQS1B and generates the duty detection signal DOUT in response to detecting duty cycles of the internal strobe signals IDQS1 and IDQS1B. The duty cycle monitoring circuit 614 reduces the duty cycles of the internal strobe signals IDQS1 and IDQS1B by the same period of time, thereby generating input signals such as the input signals IN1 and IN2 of FIG. 8, respectively. The duty cycle monitoring circuit 614 generates the duty detection signal DOUT by detecting duty cycles of the input signals. The duty cycle monitoring circuit 614 may have a configuration substantially similar to the configuration of the duty cycle monitoring circuit 500 illustrated in FIG. 8 and may perform substantially the same functions. In an embodiment, the duty cycle monitoring circuit 614 may be implemented with one of the duty cycle monitoring circuits 100 of FIGS. 1 and 200 of FIG. 3. The duty cycle monitoring circuit 614 receives an enable signal EN and a flip signal FL. The enable signal EN activates the duty cycle monitoring circuit 614 and controls or triggers the duty cycle monitoring circuit 614 to perform a duty monitoring operation. The enable signal EN may correspond to the enable signal EN illustrated in FIG. 1. When the flip signal FL is at a first logic level, the duty cycle monitoring circuit 614 generates the duty detection signal DOUT by detecting a duty cycle of the first internal strobe signal IDQS1 relative to a duty cycle of the second internal strobe signal IDQS1B. For example, the duty cycle monitoring circuit 614 detects whether the duty cycle of the first internal strobe signal IDQS1 is greater than the duty cycle of the second internal strobe signal IDQS1B and changes the logic level of the duty detection signal DOUT accordingly. When the flip signal FL is at a second logic level, the duty cycle monitoring circuit 614 generates the duty detection signal DOUT by detecting the duty cycle of the second internal strobe signal IDQS1B relative to the duty cycle of the first internal strobe signal IDQS1. For example, the duty cycle monitoring circuit 614 detects whether the duty cycle of the second internal strobe signal IDQS1B is greater than the duty cycle of the first internal strobe signal IDQS1 and changes the logic level of the duty detection signal DOUT accordingly. When the duty cycle difference between the internal strobe signals IDQS1 and IDQS1B remains constant, the logic level of the duty detection signal DOUT when the flip signal FL is at the first logic level is opposite to the logic level of the duty detection signal DOUT when the flip signal FL is at the second logic level.

The semiconductor apparatus 600 includes a first clock distribution circuit 615 and a data error transmission circuit 616. The first clock distribution circuit 615 is electrically coupled between the first duty adjustment circuit 612 and the data reception circuit 613. The first clock distribution circuit 615 receives the internal strobe signals IDQS1 and IDQS1B from the first duty adjustment circuit 612 and distributes the internal strobe signals IDQS1 and IDQS1B to the data reception circuit 613. Although not illustrated, the semiconductor apparatus 600 includes a plurality of data reception circuits corresponding to the quantity of data channels, and the first clock distribution circuit 615 distributes the internal strobe signals IDQS1 and IDQS1B to the plurality of data reception circuits. The data error transmission circuit 616 is electrically coupled to the data error pad 608 and transmits a data error signal DERR to the external device. During normal operation, the data error transmission circuit 616 transmits to the external device as the data error signal DERR a result of error detection within internal data of the semiconductor apparatus 600. The data error transmission circuit 616 is electrically coupled to the duty cycle monitoring circuit 614. During the duty monitoring operation, the data error transmission circuit 616 transmits the duty detection signal DOUT, received from the duty cycle monitoring circuit 614, to the external device as the data error signal DERR. During the duty monitoring operation, the external device receives the duty detection signal DOUT within the data error signal DERR. When the semiconductor apparatus 600 transmits the duty detection signal DOUT to the external device via the data error transmission circuit 616 and the data error pad 608, the semiconductor apparatus 600 may not include a separate pad to transmit the duty detection signal DOUT.

The semiconductor apparatus 600 includes a second duty adjustment circuit 617, a data transmission circuit 618, and a strobe transmission circuit 619. The second duty adjustment circuit 617 receives the first internal strobe signal IDQS1, the second internal strobe signal IDQS1B, and a second duty control signal RDC. The second duty adjustment circuit 617 generates a third internal strobe signal IDQS2 and a fourth internal strobe signal IDQS2B by adjusting the duty cycles of the internal strobe signals IDQS1 and IDQS1B based on the second duty control signal RDC. The second duty adjustment circuit 617 adjusts the duty cycles of one or both of the internal strobe signals IDQS1 and IDQS1B based on the second duty control signal RDC and generates the internal strobe signals IDQS2 and IDQS2B with adjusted duty cycles. The second duty control signal RDC is generated based on the result of the duty monitoring operation of the duty cycle monitoring circuit 614 and/or the duty detection signal DOUT. The data transmission circuit 618 receives the internal strobe signals IDQS2 and IDQS2B and the internal data of the semiconductor apparatus 600. The data transmission circuit 618 outputs the internal data of the semiconductor apparatus 600 as the data DQ in synchronization with the internal strobe signals IDQS2 and IDQS2B. The data transmission circuit 618 transmits the data DQ to the external device. The strobe transmission circuit 619 receives the internal strobe signals IDQS2 and IDQS2B. The strobe transmission circuit 619 generates the strobe signals RDQS and RDQSB based on the internal strobe signals IDQS2 and IDQS2B. The strobe transmission circuit 619 generates the strobe signals RDQS and RDQSB by driving voltages of the internal strobe signals IDQS2 and IDQS2B and transmitting the strobe signals RDQS and RDQSB to the external device through the strobe pads 606 and 607.

The semiconductor apparatus 600 includes a second clock distribution circuit 621, a command control circuit 622, and a clock receiver 623. The second clock distribution circuit 621 is electrically coupled between the second duty adjustment circuit 617 and the data transmission circuit 618 and between the second duty adjustment circuit 617 and the strobe transmission circuit 619. The second clock distribution circuit 621 receives the internal strobe signals IDQS2 and IDQS2B from the second duty adjustment circuit 617 and distributes the internal strobe signals IDQS2 and IDQS2B to the data transmission circuit 618 and the strobe transmission circuit 619. Although not illustrated, the semiconductor apparatus 600 may include a plurality of data transmission circuits based on the quantity of data channels, and the second clock distribution circuit 621 distributes the internal strobe signals IDQS2 and IDQS2B to the plurality of data transmission circuits. The command control circuit 622 receives the command address signal CA from the external device through the command address pad 603. The command control circuit 622 generates an internal command signal INCMD based on the command address signal CA to enable the semiconductor apparatus 600 to perform various operations. The command control circuit 622 generates the first duty control signal WDC, the enable signal EN, the flip signal FL, and the second duty control signal RDC based on the command address signal CA. When the semiconductor apparatus 600 performs the duty monitoring operation, the external device receives the duty detection signal DOUT through the data error signal DERR and generates the command address signal CA based on the duty detection signal DOUT. The command control circuit 622 generates the first duty control signal WDC, the flip signal FL, and the second duty control signal RDC according to information included in the command address signal CA. The command control circuit 622 provides the first duty control signal WDC to the first duty adjustment circuit 612, provides the enable signal EN and the flip signal FL to the duty cycle monitoring circuit 614, and provides the second duty control signal RDC to the second duty adjustment circuit 617. The clock receiver 623 may receive the system clock signal CK transmitted from the external device through the clock pad 604. The clock receiver 623 generates a reference clock signal RCK by buffering the system clock signal CK and provide the reference clock signal RCK to the command control circuit 622. The command address signal CA is transmitted from the external device to the semiconductor apparatus 600 in synchronization with the system clock signal CK.

The command control circuit 622 includes a command decoder 622-1 and a mode register 622-2. The command decoder 622-1 receives the command address signal CA and the reference clock signal RCK. The command decoder 622-1 latches the command address signal CA in synchronization with the reference clock signal RCK and generates various internal command signals INCMD by decoding the latched command address signal. The command decoder 622-1 generates a register command signal MRW by decoding the command address signal CA. The command decoder 622-2 provides the register command signal MRW to the mode register 622-2. The mode register 622-2 receives the register command signal MRW and stores the register command signal MRW. The mode register 622-2 stores various information based on the register command signal MRW. The mode register 622-2 outputs the first duty control signal WDC, the enable signal EN, the flip signal FL, and the second duty control signal RDC based on the information stored in the mode register 622-2.

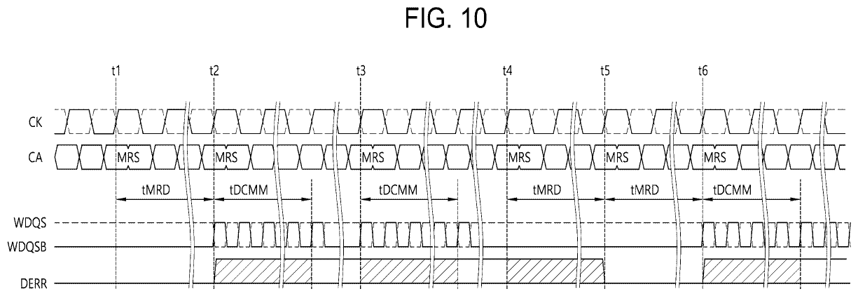

FIG. 10 is a timing diagram during operation of the semiconductor apparatus 600 according to an embodiment. Referring to FIG. 9 and FIG. 10, operation of the semiconductor apparatus 600 according to an embodiment is described. The semiconductor apparatus 600 is electrically coupled to the external device to perform the duty monitoring operation. For example, the semiconductor apparatus 600 performs the duty cycle monitoring operation during a duty cycle adjustment training operation with the external device. At time t1, the external device transmits to the semiconductor apparatus 600 the command address signal CA that includes information including a default value of the first duty control signal WDC to perform the duty cycle monitoring operation. In FIG. 10, the command address signal CA, from which the register command signal MRW is generated, is denoted as MRS. The command control circuit 622 sets the first duty control signal WDC to a default value based on the command address signal CA. After a time interval tMRD elapses at time t2, the external device transmits the command address signal CA to initiate the duty monitoring operation. The time interval tMRD includes a time interval during which the command address signal MRS associated with the register command signal MRW can be transmitted. The command address signal CA includes information that activates the duty cycle monitoring circuit 614 and information that sets the flip signal FL to a first logic level. The external device transmits the strobe signals WDQS and WDQSB to the semiconductor apparatus 600. After the command address signal CA is transmitted, the duty monitoring operation is performed during a time interval tDCMM. The interval tDCMM includes a time interval from a point in time at which the command address signal CA associated with the duty monitoring operation is transmitted to a point in time at which the data error signal DERR is transmitted from the semiconductor apparatus 600. The command control circuit 622 provides the enable signal EN and the flip signal FL at a first logic level to the duty cycle monitoring circuit 614. The duty cycle monitoring circuit 614 monitors the duty cycles of the internal strobe signals IDQS1 and IDQS1B based on the enable signal EN and the flip signal FL and generates the duty detection signal DOUT. The data error transmission circuit 616 outputs the duty detection signal DOUT within the data error signal DERR to the external device. At time t3, the external device transmits the command address signal CA that includes information that sets the flip signal FL to the second logic level. The command control circuit 622 provides the flip signal FL at the second logic level to the duty cycle monitoring circuit 614. The duty cycle monitoring circuit 614 monitors the duty cycles of the internal strobe signals IDQS1 and IDQS1B based on the flip signal FL and generates the duty detection signal DOUT. The data error transmission circuit 616 outputs the duty detection signal DOUT within the data error signal DERR to the external device. After the time interval tDCMM elapses at time t4, the external device transmits the command address signal CA to stop the duty cycle monitoring operation. The command control circuit 622 disables the enable signal EN based on the command address signal CA, and the duty cycle monitoring circuit 614 is deactivated or discontinues performing duty cycle monitoring functions. The external device provides the command address signal CA to the semiconductor apparatus at time t5 to update the value of the first duty control signal WDC when the logic level of the duty detection signal DOUT generated by the duty monitoring operation performed between time t2 and time t3 is opposite to the logic level of the duty detection signal DOUT generated by the duty monitoring operation performed between time t3 and time t4. The command control circuit 622 updates the value of the first duty control signal WDC based on the command address signal CA. The first duty adjustment circuit 612 generates the internal strobe signals IDQS1 and IDQS1B by adjusting the duty cycles of the strobe signals WDQS and WDQSB based on the first duty control signal WDC. When adjustment of the duty cycles of the first and second strobe signals WDQS and WDQSB is completed, the operations performed between time t2 and time t5 may be repeated. At time t6, the external device retransmits the command address signal CA to perform the duty monitoring operation. The command control circuit 622 provides the enable signal EN and the flip signal FL at the first logic level to the duty cycle monitoring circuit 614. The duty cycle monitoring circuit 614 monitors the respective duty cycles of the internal strobe signals IDQS1 and IDQS1B based on the enable signal EN and the flip signal FL and generates the duty detection signal DOUT. The data error transmission circuit 616 outputs the duty detection signal DOUT within the data error signal DERR to the external device. When the first duty control signal WDC is set, the second duty control signal RDC is set using the same method.

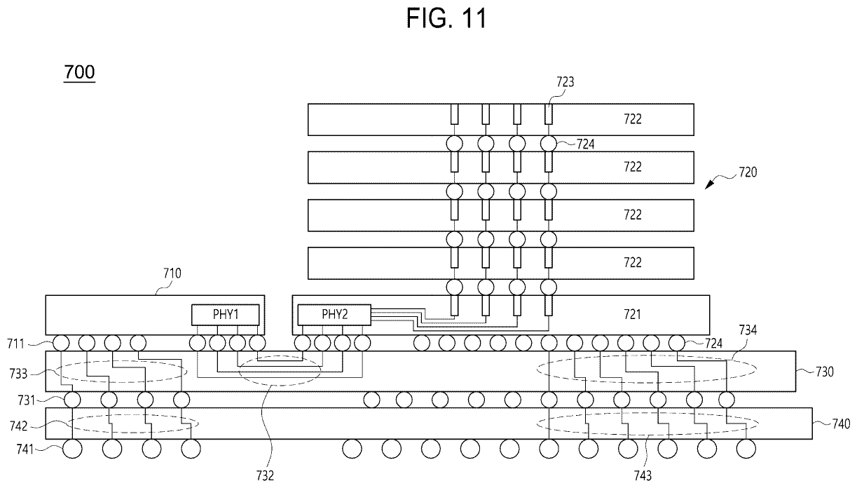

FIG. 11 is a diagram illustrating a configuration of a semiconductor system 700 in accordance with an embodiment. Referring to FIG. 11, the semiconductor system 700 includes a host device 710 and a memory device 720. The host device 710 is a master device that controls the memory device 720 and enables the memory device 720 to perform various operations. The host device 710 accesses the memory device 720 to write data to the memory device 720 and read data stored in the memory device 720. For example, the host device 710 includes one or more of a central processing unit (CPU), a graphics processing unit (GPU), a multimedia processor (MMP), a digital signal processor (DSP), an application processor (AP), a data processing unit (DPU), a neural processing unit (NPU), and a system-on-chip (SoC). The memory device 720, under control of the host device 710, stores data transmitted from the host device 710 and output data stored in the memory device 720 to the host device 710. For example, the memory device 720 is a high bandwidth memory (HBM) device.

The host device 710 may include an interface circuit PHY1. The host device 710 is electrically coupled to the memory device 720 through the interface circuit PHY1, and, via the interface circuit PHY1, transmits various signals to the memory device 720 and receives various signals from the memory device 720. The host device 710 may be a component corresponding to the external device described in FIG. 9. For example, as illustrated in FIG. 9, the host device 710 transmits the command address signal CA, the system clock signal CK, the strobe signals WDQS and WDQSB, and the data DQ to the memory device 720 through the interface circuit PHY1, and receives the strobe signals RDQS and RDQSB, the data DQ, and the data error signal DERR transmitted from the memory device 720 through the interface circuit PHY1. The memory device 720 includes a logic die 721 and a plurality of memory dies 722. The plurality of memory dies 722 is sequentially stacked on or over the logic die 721 and electrically intercoupled via through-vias 723 formed through each of the logic die 721 and the plurality of memory dies 722. The logic die 721 transfers data communication between the host device 710 and the plurality of memory dies 722. The logic die 721 includes an interface circuit PHY2 that electrically couples the host device 710 and the plurality of memory dies 722. The interface circuit PHY2 converts signals transmitted from the host device 710 into signals suitable for use in the memory device 720 and transmits the converted signals to the plurality of memory dies 722. The interface circuit PHY2 converts signals output from the plurality of memory dies 722 into signals suitable for use in the host device 710 and transmits the converted signals to the host device 710. The interface circuit PHY2 of the logic die 721 may include the configuration of the semiconductor apparatus 600 illustrated in FIG. 9. To support high bandwidth, the memory device 720 is electrically coupled to the host device 710 through a large quantity of signal transmission lines. The memory device 720 is manufactured in a form stacked with the host device 710 on or over a single substrate.

The semiconductor system 700 includes an interposer 730 and a package substrate 740. The interposer 730 is stacked on or over the package substrate 740, and the host device 710 and the memory device 720 are stacked on or over the interposer 730. The host device 710 is stacked on or over the interposer 730 in a first area, such as the left area of FIG. 11. The memory device 720 is stacked on or over the interposer 730 in a second area, such as the right area of FIG. 11. The package substrate 740, the interposer 730, the host device 710, and the memory device 720 may be enclosed within a single package. The package substrate 740 is electrically coupled to the external device utilizing a plurality of solder balls 741. Signal paths 742 and 743 that electrically couple the interposer 730 to the solder balls 741 are formed within the package substrate 740. The interposer 730 is electrically coupled to the signal paths 742 and 743 of the package substrate 740 through solder bumps 731. Signal paths 732 that electrically couple the host device 710 to the memory device 720 are formed within the interposer 730. The signal paths 732 may electrically couple the interface circuit PHY2 of the logic die 721 to the interface circuit PHY1 of the host device 710. Signal paths 733 and 734 that electrically couple the host device 710 and the memory device 720 to the package substrate 740 are formed in the interposer 730. The host device 710 is electrically coupled to the signal paths 733 of the interposer 730 through micro-bumps 711. The memory device 720 is electrically coupled to the signal paths 734 of the interposer 730 through micro-bumps 724. The logic die 721 is electrically coupled to the signal paths 734 of the interposer 730 through micro-bumps 724, and the plurality of memory dies 722 is sequentially stacked on or over the logic die 721 through micro-bumps 724. The micro-bumps 724 electrically couple the through-vias of the logic die 721 to the through-vias of the plurality of memory dies 722. The signal paths 732 of the interposer 730 that electrically couple the interface circuit PHY2 of the logic die 721 and the interface circuit PHY1 of the host device 710 may include signal transmission lines, links, a bus, or channels between the host device 710 and the memory device 720. For example, the strobe signals WDQS, WDQSB, RDQS, and RDQSB, the data DQ, the system clock signal CK, the command address signal CA, and the data error signal DERR illustrated in FIG. 9 are transmitted between the host device 710 and the memory device 720 through the signal paths 732. The signal paths 733 of the interposer 730 that electrically couple the host device 710 to the package substrate 740 may include signal transmission lines, links, a bus, or channels to allow the host device 710 to communicate with the external device. The signal paths 734 of the interposer 730 that electrically couple the logic die 721 to the package substrate 740 may be direct access paths that facilitate direct access between the external device and the memory device 720.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A duty cycle monitoring circuit comprising:
a duty cycle reduction circuit configured to receive a first clock signal and a second clock signal, to reduce a duty cycle of the first clock signal by an amount to generate a first input signal, and to reduce a duty cycle of the second clock signal by the amount to generate a second input signal;
a duty cycle detection circuit configured to detect the duty cycle of the first input signal and the second input signal to generate a first output signal and a second output signal; and
a latch circuit configured to generate a duty detection signal when one of the first output signal and the second output signal reaches a trigger voltage.

2. The duty cycle monitoring circuit of claim 1, wherein the duty cycle reduction circuit is configured to generate the first input signal and the second input signal having duty cycles reduced compared to the duty cycles of the first clock signal and the second clock signals by adjusting pulse widths of the first clock signal and the second clock signals, respectively.

3. The duty cycle monitoring circuit of claim 1, wherein the duty cycle reduction circuit comprises:
a first reduction circuit configured to reduce the duty cycle of the first clock signal by the amount to generate the first input signal; and
a second reduction circuit configured to reduce the duty cycle of the second clock signal by the amount to generate the second input signal.

4. The duty cycle monitoring circuit of claim 3,
wherein the first reduction circuit comprises a buffer circuit configured to buffer the first clock signal to generate the first input signal; and
wherein a threshold voltage of the buffer circuit is higher than an intermediate voltage level of a swing range of the first clock signal.

5. The duty cycle monitoring circuit of claim 3, wherein the first reduction circuit comprises:
a first inverter configured to invert the first clock signal and output the inverted signal on a first node;
a second inverter configured to invert the inverted signal and output the first input signal on the second node; and
a threshold voltage regulator configured to pull-down drive a voltage at the second node based on the inverted signal and a threshold adjustment signal.

6. The duty cycle monitoring circuit of claim 3, wherein the first reduction circuit comprises a pulse generator configured to generate the first input signal having a rising edge that occurs at a point in time later than a rising edge of the first clock signal.

7. The duty cycle monitoring circuit of claim 6, wherein the pulse generator comprises:
an odd number of inverters configured to delay the first clock signal;
a NAND gate configured to receive an output signal of a final stage of the odd number of inverters and a power supply voltage and generate a delayed output signal; and
an AND gate configured to receive the first clock signal and the delayed output signal and generate the first input signal.

8. The duty cycle monitoring circuit of claim 1, wherein the duty cycle detection circuit is configured to discharge a first capacitor electrically coupled to a first output node for a time interval corresponding to a pulse width of the first input signal to generate the first output signal, and to discharge a second capacitor electrically coupled to a second output node for a time interval corresponding to a pulse width of the second input signal to generate the second output signal.

9. The duty cycle monitoring circuit of claim 1, wherein the latch circuit is configured to generate the duty detection signal at a first logic level when the first output signal is at a voltage level lower than a voltage level of the trigger voltage and to generate the duty detection signal at a second logic level when the second output signal is at a voltage level lower than the voltage level of the trigger voltage.

10. A duty cycle monitoring circuit comprising:
a clock chopper circuit configured to receive a first clock signal and a second clock signal and to output, based on a flip signal, a first of the first clock signal and the second clock signal as a first select clock signal and a second of the first clock signal and the second clock signal as a second select clock signal;
a duty cycle reduction circuit configured to reduce duty cycles of the first select clock signal and the second select clock signal by an amount to generate a first input signal and a second input signal;
a duty cycle detection circuit configured to detect duty cycles of the first input signal and the second input signal to generate a first output signal and a second output signal; and
a latch circuit configured to generate a duty detection signal based on the first output signal and the second output signal.

11. The duty cycle monitoring circuit of claim 10, wherein the clock chopper circuit is configured to output the first clock signal as the first select clock signal and the second clock signal as the second select clock signal when the flip signal is at a first logic level and to output the second clock signal as the first select clock signal and the first clock signal as the second select clock signal when the flip signal is at a second logic level.

12. The duty cycle monitoring circuit of claim 10, wherein the duty cycle reduction circuit is configured to generate the first input signal and the second input signals having duty cycles reduced compared to the duty cycles of the first select clock signal and the second select clock signals by adjusting pulse widths of the first select clock signal and the second select clock signal, respectively.

13. The duty cycle monitoring circuit of claim 10, wherein the duty cycle reduction circuit comprises:
a first reduction circuit configured to reduce the duty cycle of the first clock signal by the amount to generate the first input signal; and
a second reduction circuit configured to reduce the duty cycle of the second clock signal by the amount to generate the second input signal.

14. The duty cycle monitoring circuit of claim 10, wherein the duty cycle detection circuit is configured to discharge a first capacitor electrically coupled to a first output node for a time interval corresponding to a pulse width of the first input signal to generate the first output signal and to discharge a second capacitor electrically coupled to a second output node for a time interval corresponding to a pulse width of the second input signal to generate the second output signal.

15. The duty cycle monitoring circuit of claim 10, wherein the latch circuit is configured to generate the duty detection signal at a first logic level when the first output signal is at a voltage level lower than a trigger voltage level and to generate the duty detection signal at a second logic level when the second output signal is at a voltage level lower than the trigger voltage level.

16. A semiconductor apparatus comprising:
a strobe reception circuit configured to receive a first strobe signal and a second strobe signal from an external device;
a first duty adjustment circuit configured to adjust duty cycles of the first strobe signal and the second strobe signal based on a first duty control signal to generate a first internal strobe signal and a second internal strobe signal, respectively;
a data reception circuit configured to receive data in synchronization with the first internal strobe signal and the second internal strobe signal; and
a duty cycle monitoring circuit configured to reduce the duty cycles of the first internal strobe signal and the second internal strobe signal by an amount to generate a first input signal and a second input signal and to detect the duty cycles of the first input signal and the second input signal to generate a duty detection signal;
wherein the first duty control signal is generated based on the duty detection signal.

17. The semiconductor apparatus of claim 16, further comprising a data error transmission circuit configured to output, to the external device, the duty detection signal within a data error signal.

18. The semiconductor apparatus of claim 16, wherein the duty cycle monitoring circuit is configured to:
receive a flip signal;
generate the duty detection signal by detecting the duty cycle of the first input signal relative to the duty cycle of the second input signal when the flip signal is at a first logic level; and
generate the duty detection signal by detecting the duty cycle of the second input signal relative to the duty cycle of the first input signal when the flip signal is at a second logic level.

19. The semiconductor apparatus of claim 18, further comprising a command control circuit configured to receive a command address signal from the external device and to generate the first duty control signal and the flip signal based on the command address signal.

20. The semiconductor apparatus of claim 16, further comprising:
a second duty adjustment circuit configured to adjust the duty cycles of the first internal strobe signal and the second internal strobe signal based on a second duty control signal to generate a third internal strobe signal and a fourth internal strobe signal;
a data transmission circuit configured to output the data in synchronization with the third internal strobe signal and the fourth internal strobe signal; and
a strobe transmission circuit configured to generate a third strobe signal and a fourth strobe signal based on the third internal strobe signal and fourth internal strobe signal, respectively.

21. The semiconductor apparatus of claim 20, further comprising a command control circuit configured to receive a command address signal from the external device and to generate the second duty control signal based on the command address signal.

22. A method comprising:
reducing a duty cycle of a first clock signal by an amount to generate a first input signal and reducing a duty cycle of a second clock signal by the amount to generate a second input signal;
generating a first output signal based on a duty cycle of the first input signal and generating a second output signal based on a duty cycle of the second input signal; and
generating a duty detection signal when one of the first output signal and the second output signal reaches a trigger voltage.
